(19) United States
(12) Patent Application Publication
(10) Pub. No.: US 2011/0127584 A1
(43) Pub. Date: Jun. 2, 2011

(54) METHOD FOR MANUFACTURING INFRARED IMAGE SENSOR AND INFRARED IMAGE SENSOR

(76) Inventors: Naoki Ushiyama, Yawata-shi (JP); Koji Tsuji, Suita-shi (JP)

(21) Appl. No.: 13/055,093

(22) PCT Filed: Jul. 24, 2009
(86) PCT No.: PCT/JP2009/063241

§ 371 Date: Jan. 20, 2011

(30) Foreign Application Priority Data
Jul. 25, 2008 (JP) 2008-192751

(51) Int. Cl. H01L 29/78; H01L 21/36

(52) U.S. Cl. 257/252; 438/54; 257/E29.347; 257/E21.461

(57) ABSTRACT

In the method for manufacturing the infrared image sensor, first, a thermal insulation layer (33) is made by forming a silicon dioxide film (31) on a first area (A1) followed by forming a silicon nitride film (32) on the silicon dioxide film (31). The silicon dioxide film (31) has compression stress. The first area (A1) is reserved in a surface of a silicon substrate (1) for forming an infrared detection element (3). The silicon nitride film (32) has tensile stress. Next, a well region (41) is formed in a second area (A2) reserved in the surface of the silicon substrate (1) for forming a MOS transistor (4). After that, a gate insulation film (45) of the MOS transistor (4) is formed by means of thermal oxidation of the surface of the silicon substrate (1). Thereafter, a temperature detection element (36) is formed on the thermal insulation layer (33). Subsequently, a drain region (43) and a source region (44) of the MOS transistor (4) are formed in the well region (41). Finally, a cavity (11) for thermal insulation is formed in a portion of the silicon substrate (1) corresponding to the infrared detection element (3).

### TECHNICAL FIELD

The present invention is directed to a method for manufacturing an infrared image sensor and an infrared image sensor.

### BACKGROUND ART

Japanese patent laid-open publication No. 2006-170937 (document 1) discloses an infrared sensor (infrared image sensor) which includes a silicon substrate, and a plurality of cells (so-called pixels) formed on a surface of the silicon substrate. Each of the pixels includes a thermal type infrared detection element configured to detect infrared, and a MOS transistor configured to read out an output of the infrared detection element and arranged adjacent to the infrared detection element. The silicon substrate is provided with cavities for thermal insulation in its portions respectively corresponding to the infrared detection elements of the pixels.

Besides, the aforementioned infrared detection element includes a supporting member, an infrared absorption member, and two beam members. The supporting member is shaped into a rectangular frame shape and is formed on the surface of the silicon substrate. The infrared absorption member is shaped into a rectangular shape and is disposed inside the supporting member. Each of the beam members connects the supporting member to the infrared absorption member.

In order to form the aforementioned infrared detection element, a first silicon dioxide film is formed on the surface of the silicon substrate. Next, a second silicon dioxide film is formed on the first silicon dioxide film. Thereafter, a temperature detection element (e.g., thermopile, and thermocouple) is formed on the second silicon dioxide film. Subsequently, a third silicon dioxide film is formed over the second silicon dioxide film to cover the thermopile.

The infrared detection element is formed by patterning a laminate composed of the first silicon dioxide film, the second silicon dioxide film, the temperature detection element, and the third silicon dioxide film.

In the above document 1, in a process of forming the MOS transistor, a warp of the infrared detection element may occur when a residual stress of the infrared detection element is changed. In this instance, the infrared detection element may have a poor stability regarding its configuration, and have a poor sensitivity.

Besides, in order to improve the sensitivity of the infrared image sensor disclosed in the above document 1, it is required to increase a temperature variation caused by infrared absorption. For example, to thin each beam member for decreasing thermal conductance thereof is proposed.

However, the infrared absorption member and each beam member of the infrared detection element are made of silicon dioxide films (the first to third silicon dioxide films). Therefore, the beam member is likely to be deformed, thereby warped.

### DISCLOSURE OF INVENTION

In view of the above insufficiency, the present invention has been aimed to propose a method of manufacturing an infrared image sensor and an image sensor which is capable of making infrared detection elements thin, yet keeping them free from warp.

An infrared image sensor manufactured by the method for manufacturing an infrared image sensor in accordance with the present invention includes a silicon substrate, and a plurality of cells formed over a surface of the silicon substrate. Each of the cells includes an infrared detection element configured to detect an infrared, and a MOS transistor configured to read out an output of the infrared detection element, the MOS transistor being arranged adjacent to the infrared detection element. The silicon substrate is provided with cavities for thermal insulation in its portions respectively corresponding to the infrared detection elements of the cells. Each of the infrared detection elements includes a thermal insulation layer formed over the surface of the silicon substrate, and a temperature detection element formed on the thermal insulation layer. The thermal insulation layer includes a silicon dioxide film for thermal insulation formed on the surface of the silicon substrate, and a silicon nitride film for thermal insulation formed on the silicon dioxide film, the silicon dioxide film having compression stress, and the silicon nitride film having tensile stress. The temperature detection element is configured to absorb infrared and detect temperature change resulting form infrared absorption. The MOS transistor including a well region of a first conductivity type formed in the surface of the silicon substrate, a drain region of a second conductivity type formed in the well region, a source region of the second conductivity type formed in the well region so as to be away from the drain region, and a gate insulation film formed on a part of the well region formed between the drain region and the source region.

The method for manufacturing the infrared image sensor includes a thermal insulation layer forming step, a well region forming step, a gate insulation film forming step, a temperature detection element forming step, a drain region and source region forming step, and a cavity forming step. The thermal insulation layer forming step is defined as a step of forming the thermal insulation layer over a first area of the surface of the silicon substrate. The well region forming step is defined as a step of forming the well region formed in a second area of the surface of the silicon substrate after the thermal insulation layer forming step. The gate insulation film forming step is defined as a step of forming the gate insulation film by means of thermal oxidation of the surface of the silicon substrate after the well region forming step. The temperature detection element forming step is defined as a step of forming the temperature detection element after the gate insulation film forming step. The drain region and source region forming step is defined as a step of forming the drain region and the source region after the temperature detection element forming step. The cavity forming step is defined as a step of forming the cavity after the drain region and source region forming step.

According to the present invention, the thermal insulation layer is completed by forming the silicon nitride film on the silicon dioxide film prior to formation of the MOS transistor. This silicon nitride film is hard to be oxidized. Therefore, it is possible to prevent the surface of the thermal insulation layer from being thermally oxidized during formation of the MOS transistor (formation of the well region, the gate insulation film, the drain region, and the source region). Accordingly, the thermal insulation layer can be free from change in at least one of the film thickness and the film configuration. Further, the thermal insulation layer is completed by forming the silicon nitride film having tensile stress on the silicon dioxide film having compression stress. Therefore, it is possible to provide the infrared image sensor which is capable of making infrared detection elements thin, yet keeping them free from warp.

In a preferred aspect, the method for manufacturing the infrared image sensor further includes an interlayer dielectric film forming step of forming an interlayer dielectric film over the surface of the silicon substrate by depositing a BPSG film over the surface of the silicon substrate followed by reflowing the deposited BPSG film, after the drain region and source region forming step and before the cavity forming layer. The method further includes a metal line forming step of forming a metal line electrically connecting the temperature detection element with the MOS transistor, after the interlayer dielectric film forming step and before cavity forming step. Moreover, the method includes a passivation film forming step of forming a passivation film on the interlayer dielectric film, after the metal line forming step and before the cavity forming step.

With this preferred aspect, the interlayer dielectric film can have an improved flatness. Therefore, it is possible to avoid breakage of the metal line due to an excess thermal stress or the like.

In a more preferred aspect, the method for manufacturing the infrared image sensor includes a recess forming step of forming a recess, after the well region forming step and before the interlayer dielectric film forming step. The well region forming step includes a step of forming a thermally-oxidized film on the second area so as to be adjacent to the thermal insulation layer. The recess forming step includes a step of forming, at a border between the thermal insulation layer and the thermally-oxidized film, the recess having a depth of the recess which is small relative to a height difference between the thermal insulation layer and the thermally-oxidized film.

With this preferred aspect, the interlayer dielectric film can have a more improved flatness. Therefore, it is possible to successfully avoid breakage of the metal line due to an excess thermal stress or the like.

In another preferred aspect, the method further includes a step of forming the infrared detection element to satisfy following two formulae:

∫_{-t/2}^{t/2}σₘ(y)dy=0 [Formula 1]

∫_{-t/2}^{t/2}σₘ(y)·ydy=0 [Formula 2]

wherein y denotes a distance from a center of the infrared detection element along a direction aligned with a thickness direction of the infrared detection element, and sₘ(y) denotes a stress of the infrared detection element, and t denotes a thickness of the infrared detection element.

With this preferred aspect, it is possible to reduce residual stress of the infrared detection element down to zero, and to reduce a bending moment of the infrared detection element down to zero. Therefore, it is possible to keep the infrared detection element free from a warp.

In another preferred aspect, the method for manufacturing the infrared image sensor further comprising a step of keeping a temperature of the silicon dioxide film less than a temperature required for forming the silicon dioxide film and of keeping a temperature of the silicon nitride film less than a temperature required for forming the silicon nitride film, after the thermal insulation layer forming step.

With this preferred aspect, it is possible to protect the film thicknesses and stresses of each of the silicon dioxide film and the silicon nitride film from undesired effect caused by a process temperature of a step performed after the thermal insulation layer forming step. Consequently, it is possible to successfully prevent occurrence of a warp of the infrared detection element.

The infrared image sensor in accordance with the present invention includes a silicon substrate, a plurality of cells formed over a surface of the silicon substrate. Each of the cells includes an infrared detection element configured to detect an infrared, and a MOS transistor configured to read out an output of the infrared detection element, the MOS transistor being arranged adjacent to the infrared detection element. The silicon substrate is provided with cavities for thermal insulation in its portions respectively corresponding to the infrared detection for thermal insulation formed on the silicon dioxide film, the silicon dioxide film having compression stress, and the silicon nitride film having tensile stress. The temperature detection element is configured to absorb infrared and detect temperature change resulting form infrared absorption. The MOS transistor includes a well region of a first conductivity type formed in the surface of the silicon substrate, a drain region of a second conductivity type formed in the well region, a source region of the second conductivity type formed in the well region so as to be away from the drain region, and a gate insulation film formed on a part of the well region formed between the drain region and the source region. The silicon nitride film is formed not to be overlapped with the well region in its thickness direction.

According to the present invention, the thermal insulation layer is completed by forming the silicon nitride film having tensile stress on the silicon dioxide film having compression stress. Therefore, even if the MOS transistor is formed by use of a common method, it is possible to prevent a warp of the infrared detection element yet thinning the infrared detection element. In addition, the silicon nitride film is hard to be oxidized. Consequently, with completing the thermal insulation layer by forming the silicon nitride film on the silicon dioxide film prior to formation of the MOS transistor, it is possible to prevent the thermal insulation layer from being thermally oxidized when the MOS transistor is formed. Thus, it is possible to prevent the thermal insulation layer from being changed in at least one of the film thickness and the film configuration.

In a preferred aspect, the infrared image sensor includes a thermally-oxidized film formed over the surface of the silicon substrate so as to be adjacent to the thermal insulation layer, an interlayer dielectric film formed over the surface of the silicon substrate so as to cover a border between the thermal insulation layer and the thermally-oxidized film, and a metal line formed on the interlayer dielectric film so as to connect the temperature detection element with the MOS transistor. The interlayer dielectric film is formed by means of reflowing a BPSG film deposited over the surface of the silicon substrate.

With this preferred aspect, the interlayer dielectric film can have an improved flatness. Therefore, it is possible to avoid breakage of the metal line due to an excess thermal stress or the like.

In another preferred aspect, the infrared image sensor includes a thermally-oxidized film formed over the surface of the silicon substrate so as to be adjacent to the thermal insulation layer, a recess formed at a border between the thermal insulation layer and the thermally-oxidized film, an interlayer dielectric film formed over the surface of the silicon substrate so as to cover the recess, and a metal line formed on the interlayer dielectric film so as to connect the temperature detection element with the MOS transistor. The interlayer dielectric film is formed by means of reflowing a BPSG film deposited over the surface of the silicon substrate.

With this preferred aspect, the interlayer dielectric film can have a more improved flatness. Therefore, it is possible to successfully avoid breakage of the metal line due to an excess thermal stress or the like.

### BRIEF DESCRIPTION OF DRAWINGS

FIG. 1A is a schematic plain view illustrating an infrared image sensor of the first embodiment,

FIG. 1B is a schematic plain view illustrating a cell of the infrared image sensor of the first embodiment,

FIG. 1C shows a schematic cross sectional view of the infrared image sensor of the first embodiment along the line A-A′ of FIG. 1B,

FIG. 2 is a circuit view illustrating the above infrared image sensor,

FIG. 3A is a schematic cross sectional view illustrating a method for manufacturing the above infrared image sensor,

FIG. 3B is a schematic cross sectional view illustrating the method for manufacturing the above infrared image sensor,

FIG. 3C is a schematic cross sectional view illustrating the method for manufacturing the above infrared image sensor,

FIG. 4A is a schematic cross sectional view illustrating the method for manufacturing the above infrared image sensor,

FIG. 4B is a schematic cross sectional view illustrating the method for manufacturing the above infrared image sensor,

FIG. 4C is a schematic cross sectional view illustrating the method for manufacturing the above infrared image sensor,

FIG. 5A is a schematic cross sectional view illustrating the method for manufacturing the above infrared image sensor,

FIG. 5B is a schematic cross sectional view illustrating the method for manufacturing the above infrared image sensor,

FIG. 6A is an explanatory view illustrating the method for manufacturing the above infrared image sensor,

FIG. 6B is an explanatory view illustrating the method for manufacturing the above infrared image sensor,

FIG. 7A is a schematic cross sectional view illustrating the method for manufacturing the above infrared image sensor,

FIG. 7B is a schematic cross sectional view illustrating the method for manufacturing the above infrared image sensor,

FIG. 7C is a schematic cross sectional view illustrating the method for manufacturing the above infrared image sensor,

FIG. 7D is a schematic cross sectional view illustrating the method for manufacturing the above infrared image sensor,

FIG. 8 is a schematic cross sectional view illustrating a method for manufacturing the above infrared image sensor according to the second embodiment,

FIG. 9A is a schematic cross sectional view illustrating the method for manufacturing the above infrared image sensor,

FIG. 9B is a schematic cross sectional view illustrating the method for manufacturing the above infrared image sensor,

FIG. 9C is a schematic cross sectional view illustrating the method for manufacturing the above infrared image sensor, and

FIG. 9D is a schematic cross sectional view illustrating the method for manufacturing the above infrared image sensor.

### BEST MODE FOR CARRYING OUT THE INVENTION

### First Embodiment

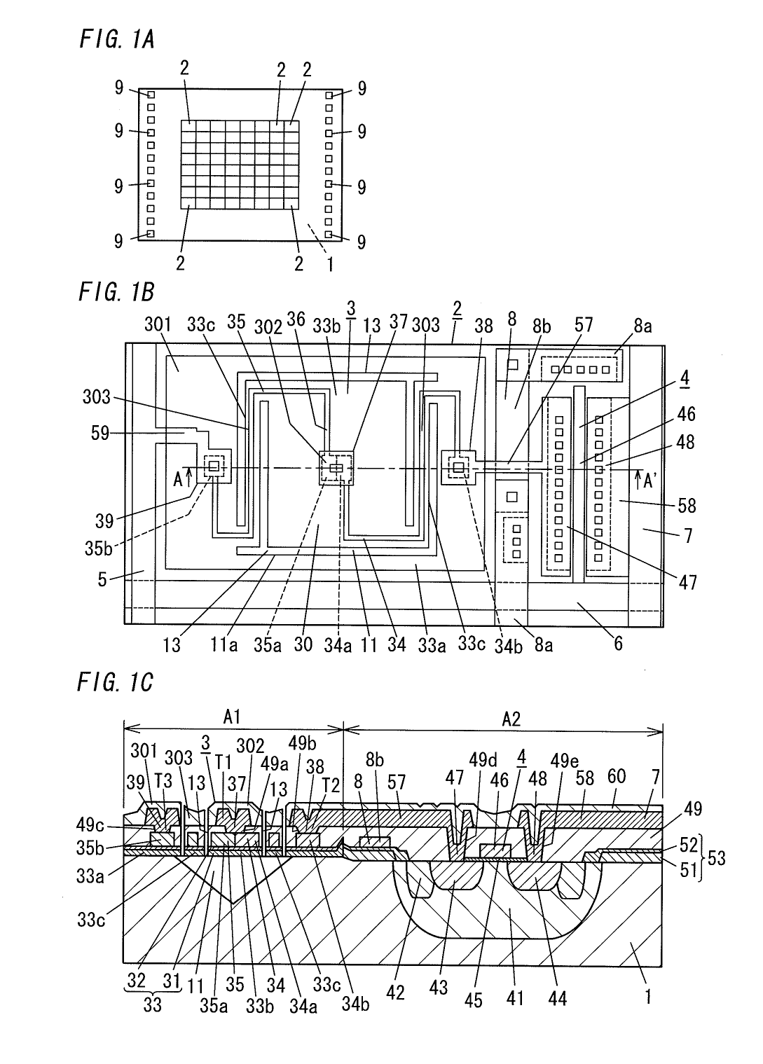

As shown in FIGS. 1A to 1C, an infrared image sensor of the first embodiment includes a silicon substrate 1, and a plurality of cells (pixels) 2 formed on a surface (upper surface, in FIG. 10) of the silicon substrate 1.

Each of the cells 2 includes a thermal type infrared detection element 3 configured to detect infrared, and a MOS transistor 4 placed adjacent to the infrared detection element 3. The MOS transistor 4 is a switching element for pixel selection, which is configured to read out an output of the infrared detection element 3. The plural cells 2 are arranged on the surface of the silicon substrate 1 in a two dimensional array (matrix) manner. Besides, in the present embodiment, m×n (8×8, in the illustrated instance) cells 2 are formed on the surface of the single silicon substrate 1. The number and/or arrangement of the cells 2 is not limited to the present embodiment.

The silicon substrate 1 is provided with cavities 11 for thermal insulation in its portions respectively corresponding to the infrared detection elements 3 of the cells 2. In the present embodiment, the silicon substrate 1 is selected such that a conductivity type is n type and that the surface is a (100) surface. The surface of the silicon substrate 1 includes a first area A1 for forming the infrared detection element 3, and a second area A2 for forming the MOS transistor.

The infrared detection element 3 is formed on the first area (area reserved for forming the infrared detection element 3) A1 of the surface of the silicon substrate 1. The infrared detection element 3 includes a supporting member 301, an infrared absorption member 302, and a plurality (two, in the present embodiment) of beam members 303. The supporting portion 301 is formed on the surface of the silicon substrate 1. The supporting member 301 is shaped into a rectangular frame shape. The infrared absorption member 302 is disposed inside the supporting member 301. The infrared absorption member 302 is shaped into a rectangular shape. The beam member 303 connects the supporting member 301 to the infrared absorption member 302. Each of the beam members 303 is shaped into a planar shape extending from a first longitudinal end of a side edge of the infrared absorption member 302 along a direction perpendicular to the side edge and further extending along a direction from the first longitudinal end of the side edge to a second longitudinal end thereof. The beam members 303 are arranged in a rotation symmetry manner with respect to a center axis along a thickness direction of the infrared absorption member 302.

The infrared detection element 3 (a structure including the infrared absorption member 302, the beam members 303, and the supporting member 301) is formed by patterning a laminate which includes a thermal insulation layer 33 formed on the surface of the silicon substrate 1, a temperature detection element 36 formed on the thermal insulation layer 33, an interlayer dielectric film 49 formed over the thermal insulation layer 33 to cover the temperature detection element 36, and a passivation film 60 formed on the interlayer dielectric film 49.

The thermal insulation layer 33 includes a silicon dioxide film 31 for thermal insulation formed on the surface of the silicon substrate 1 with having compression stress, and a silicon nitride film 32 for thermal insulation formed on the silicon dioxide film 31 with having tensile stress. The thermal insulation layer 33 has a first portion 33a corresponding to the supporting member 301, a second portion 33b corresponding to the infrared absorption member 302, and third potions 33c respectively corresponding to the beam members 303.

The interlayer dielectric film 49 is made of a BPSG film. The passivation film 60 is a laminated film comprising a PSG film formed on the interlayer dielectric film 49 and an NSG film formed on the PSG film. Besides, the passivation film 60 and the interlayer dielectric film 49 are formed over the first area A1 and the second area A2. Each of the passivation film 60 and the interlayer dielectric film 49 has its portion which is formed over the first area A1 and functions as an infrared absorption film.

The temperature detection element 36 is configured to absorb infrared and detect a temperature variation which is caused by infrared absorption. In the present embodiment, the temperature detection element 36 is a thermocouple made of an n-type polysilicon layer 34 and a p-type polysilicon layer 35. The temperature detection element 36 may be a thermopile.

Each of the polysilicon layers 34 and 35 are formed on the thermal insulation layer 33.

Each of the polysilicon layers 34 and 35 has a planar configuration of meander shape, as shown in FIG. 1B. The polysilicon layer 34 is disposed over the second portion 33a, one of the third portions 33c (right third portion 33c, in FIG. 1B), and the first portion 33a. The polysilicon layer 35 is disposed over the second portion 33a, the other of the third portions 33c (left third portion 33c, in FIG. 1B), and the first portion 33a. The n-type polysilicon layer 34 has a first end 34a, and the p-type polysilicon layer 35 has a first end 35a. The first ends 34a and 35a contact with each other on a center of the second portion 33b of the thermal insulation layer 33. The n-type polysilicon layer 34 has a second end 34b, and the p-type polysilicon layer 35 has a second end 35b. The second ends 34b and 35b are disposed on the first portion 33a of the thermal insulation layer 33.

Moreover, the infrared detection element 3 includes electrodes 37 to 39 formed on the temperature detection element 36.

The electrode (first electrode) 37 is formed on the first ends 34a and 35a to extend from the first end 34a to the first end 35a. In addition, the first electrode 37 is electrically connected to the first ends 34a and 35a of the polysilicon layers 34 and 35 via a contact hole 49a formed in the interlayer dielectric film 49. The first electrode 37 is made of a metal (e.g., Al—Si). The first end 34a of the polysilicon 34, the first end 35a of the polysilicon 35, and the first electrode 37 constitute a hot junction T1.

The electrode (second electrode) 38 is formed on the second end 34b of the polysilicon layer 34. The second electrode 38 is electrically connected to the second end 34b of the polysilicon layers 34 via a contact hole 49b formed in the interlayer dielectric film 49. The second end 34b of the n-type polysilicon 34 and the second electrode 38 constitute a first cold junction T2.

The electrode (third electrode) 39 is formed on the second end 35b of the polysilicon layer 35. The third electrode 39 is electrically connected to the second end 35b of the polysilicon layers 35 via a contact hole 49c formed in the interlayer dielectric film 49. The second end 35b of the p-type polysilicon 35 and the third electrode 39 constitute a second cold junction T3.

Each of the electrodes 37 to 39 is electrically insulated and separated from the other electrodes by the interlayer dielectric film 49.

The MOS transistor 4 is formed on the second area (area reserved for forming the MOS transistor 4) A2 of the surface of the silicon substrate 1.

The MOS transistor 4 includes a well region 41 of a first conductivity type (p⁺-type, in the present embodiment), a drain region 43 of a second conductivity type (n⁺-type, in the present embodiment), a source region 44 of the second conductivity type, a channel-stopper region 42 of the p⁺⁺-type, a gate insulation film 45, a gate electrode 46, a drain electrode 47, and a source electrode 48.

The well region 41 is formed on the surface of the silicon substrate 1.

The drain region 43 and the source region 44 are formed in the well region 41 to be away from each other.

The channel-stopper region 42 is formed in the well region 41 to surround both the drain region 43 and the source region 44.

The gate insulation film 45 is formed on a part of the well region 41 formed between the drain region 43 and the source region 44. The gate insulation film 45 is made of a silicon dioxide film (thermally-oxidized film).

The gate electrode 46 is formed on the gate insulation film 45. The gate electrode 46 is made of a polysilicon layer.

The drain electrode 47 is formed over the drain region 43. The drain electrode 47 is electrically connected to the drain region 43 via a contact hole 49d formed in the interlayer dielectric film 49.

The source electrode 48 is formed over the source region 44. The source electrode 48 is electrically connected to the source region 44 via a contact hole 49e formed in the interlayer dielectric film 49.

The interlayer dielectric film 49 isolates and separates the gate electrode 46, the drain electrode 47, and the source electrode 48 from the others.

Besides, in the present embodiment, the first conductivity type is defined as the p-type, and the second conductivity type is defined as the n-type. In contrast, the first conductivity type may be defined as the n-type, and the second conductivity type may be defined as the p-type.

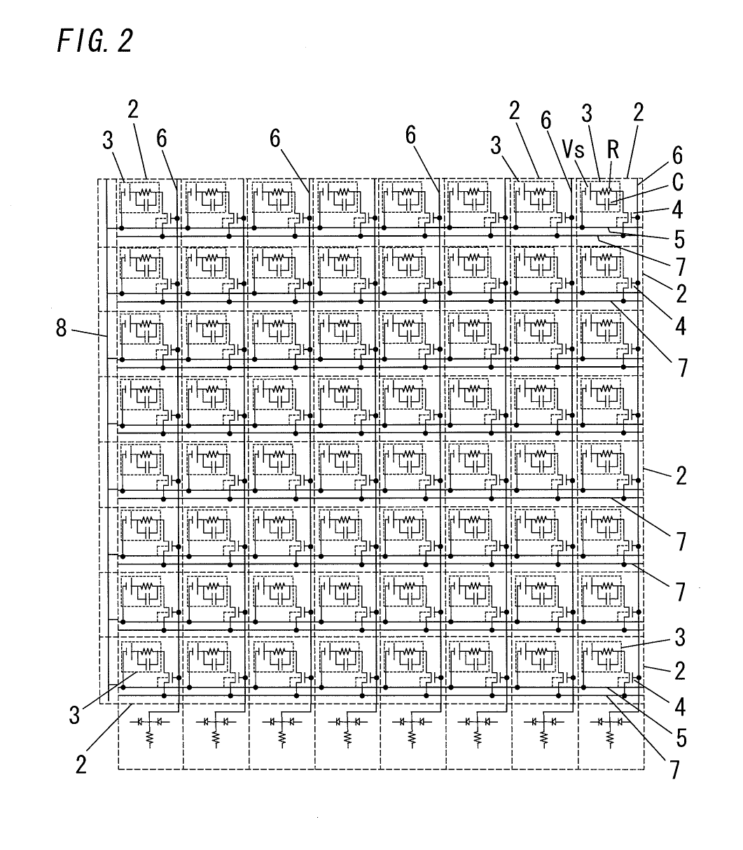

As shown in FIG. 2, the infrared image sensor of the present embodiment includes a plurality of vertical read-out lines 7, a plurality of horizontal signal lines 6, and a plurality of reference bias lines 5. Each of the vertical read-out lines 7 is connected to first ends of the temperature detection elements 36 of the infrared detection elements 3 in each row via the MOS transistors 4. Each of the horizontal signal lines 6 is connected to the MOS transistors 4 corresponding to the infrared detection elements 36 in each column. Each of the reference bias lines 5 is connected to second ends of the temperature detection elements 36 of the infrared detection elements 3 in each row.

Especially, in the present embodiment, the MOS transistor 4 has its gate electrode 46 connected to the horizontal signal line 6. Further, the drain electrode 47 is connected to the reference bias line 5 through the temperature detection element 36. Moreover, the source electrode 48 is connected to the vertical read-out line 7.

Each reference bias line 5, each horizontal signal line 6, each vertical read-out line 7, and a common ground line 8 are electrically connected to corresponding pads 9, respectively.

Accordingly, by controlling potentials of the pads 9 to sequentially turn on the MOS transistors 4, it is enabled to read out a time-series data of the outputs from the infrared detection elements 3. Besides, in FIG. 2, the temperature detection element 36 is illustrated as its equivalent circuit including a voltage source Vs corresponding to thermal electromotive force of the temperature detection element 36, a resistor R connected in series with the voltage source Vs, and a capacitor C connected in parallel with the resistor R.

In each cell 2 of the infrared image sensor of the present embodiment, the MOS transistor 4 has its drain electrode 47 connected to the second electrode 38 by use of a metal line (e.g., Al—Si line) 57. The drain electrode 47, the second electrode 38, and the metal line 57 are formed integrally with each other. The third electrode 39 is electrically connected to the reference bias line 5 by use of a metal line (e.g., Al—Si line) 59. The third electrode 39, the reference bias line 5, and the metal line 59 are formed integrally with each other. The MOS transistor 4 has its source electrode 48 connected to the vertical read-out line 7 by use of a metal line (e.g., Al—Si line) 58. The source electrode 48, the vertical read-out line 7, and the metal line 58 are formed integrally with each other. The gate electrode 46 is electrically connected to the horizontal signal line 6 which is a polysilicon line. The gate electrode 46 and the horizontal signal line 6 are formed integrally with each other.

In addition, as shown in FIGS. 1B and 1C, the channel-stopper region 42 is electrically connected to the common ground line 8. The common ground line 8 is used to give lower potential to the channel-stopper region 42 than (that given) to the drain region 43 and the source region 44 for mutual isolation of the elements (for isolating the element from each other). The common ground line 8 is composed of a metal line 8a and a polysilicon line 8b.

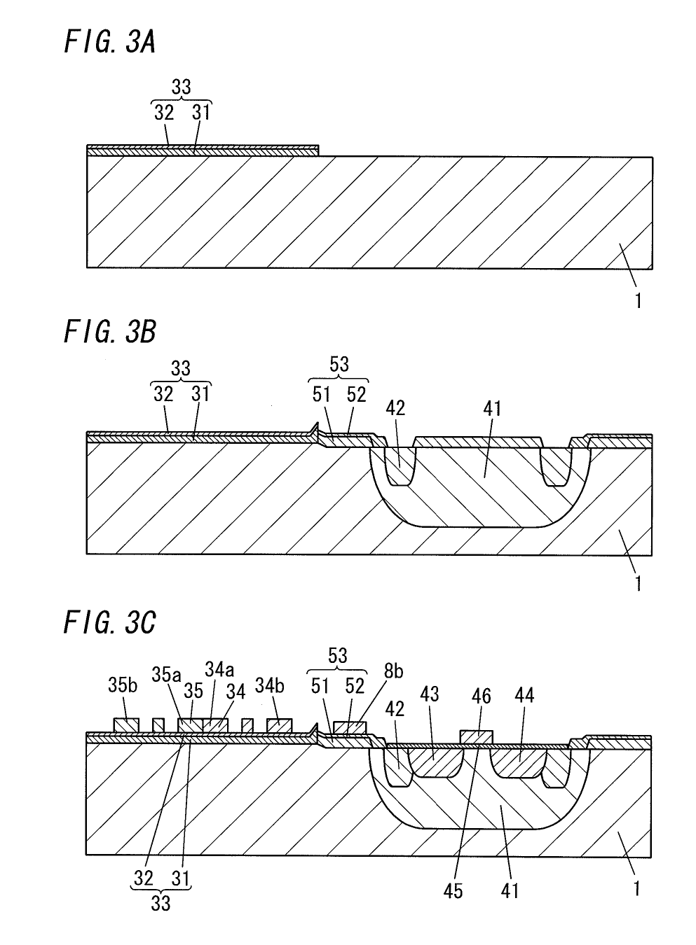

Next, with regard to FIGS. 3 to 5, an explanation is made to a method for manufacturing the infrared image sensor in accordance with the present embodiment.

The method for manufacturing the infrared image sensor of the present embodiment mainly includes a thermal insulation layer forming step, a well region forming step, a gate insulation film forming step, a temperature detection element forming step, a drain region and source region forming step, an interlayer dielectric film forming step, a metal line forming step, a passivation film forming step, and a cavity forming step.

The thermal insulation layer forming step is defined to form the thermal insulation layer 33 on the surface of the silicon substrate 1, thereby providing a structure illustrated in FIG. 3A. In the thermal insulation layer forming step, the thermal insulation layer 33 is formed on the whole of the surface of the silicon substrate 1. The thermal insulation layer 33 comprises the silicon dioxide film 31 having a first predetermined film thickness (e.g., 5000 A) and the silicon nitride film 32 having a second predetermined film thickness (e.g., 2450 A). For example, the silicon substrate 1 is thermally oxidized at a predetermined temperature (e.g., 1100 deg C.) to form the silicon dioxide film 31. The silicon dioxide film 31 formed in the above mentioned manner has residual stress of −400 MPa. That is, the silicon dioxide film 31 has compression stress (residual compression stress). Next, the silicon nitride film 32 is deposited by LPCVD technique and then is annealed at a predetermined anneal temperature (e.g., 1100 deg C.) in N₂ gas atmosphere. Thereby, the silicon nitride film 32 is formed. The silicon nitride film 32 formed in the above mentioned manner has residual stress of 1.4 GPa. That is, the silicon nitride film 32 has tensile stress (residual tensile stress). Thereafter, by use of the photolithography technique and the etching technique, a part of the thermal insulation layer 33 formed on the second area A2 is removed yet a part of the thermal insulation layer 33 formed on the first area A1 remains.

The well region forming step is performed after the thermal insulation layer forming step. The well region forming step is defined to form the well region 41 in the surface of the silicon substrate 1. Subsequently, the channel-stopper region forming step is performed. The channel-stopper forming step is defined to form the channel-stopper region 42 in the well region 41 from the surface of the silicon substrate 1.

The well region forming step is defined to thermally oxidize an exposed area of the surface of the silicon substrate 1 at a predetermined temperature to form a silicon dioxide film 51 on a desired area of the surface of the silicon substrate 1. Thereafter, the silicon dioxide film 51 is patterned by use of the photolithography technique and the etching technique together with a mask for forming the well region 41. Subsequently, the well region 41 of the p⁺-type is formed by means of the ion implantation of a p-type impurity (e.g., boron) followed by the drive-in diffusion (diffusion of impurities).

In the present embodiment, the silicon dioxide film 51 is formed by use of the thermal oxidization technique. Therefore, the silicon dioxide film 51 is not formed on the first area A1 of the surface of the silicon substrate 1. Further, in the well region forming step, the thermal oxidization and the drive-in diffusion are performed at a temperature which does not exceed both a temperature required for forming the silicon dioxide film 31 and a temperature required for forming the silicon nitride film 32, that is, a temperature of formation of the thermal insulation layer 33 (1100 deg C., in the present embodiment). In other words, the temperature of formation of the thermal insulation layer 33 is selected to exceed a process temperature of the well region forming step. Consequently, the thermal insulation layer 33 sees no substantial change in its residual stress.

The channel-stopper forming step is defined to thermally oxidize the surface of the silicon substrate 1 at a predetermined temperature to form a silicon dioxide film 52 on a desired area of the surface of the silicon substrate 1. Thereafter, the silicon dioxide film 52 is patterned by use of the photolithography technique and the etching technique together with a mask for forming the channel-stopper region 42. Subsequently, the channel-stopper region 42 of the p⁺⁺-type is formed by means of the ion implantation of a p-type impurity (e.g., boron) followed by the drive-in diffusion.

In the present embodiment, the silicon dioxide film 52 is formed by use of the thermal oxidization technique. Therefore, the silicon dioxide film 52 is not formed on the first area A1 of the surface of the silicon substrate 1. Further, the thermal oxidization and the drive-in diffusion in the channel-stopper region forming step are performed at a temperature which does not exceed the temperature of formation of the thermal insulation layer 33 (1100 deg C., in the present embodiment). Consequently, the thermal insulation layer 33 sees no substantial change in its residual stress.

The gate insulation film forming step, the temperature detection element forming step, a gate/source/drain forming step (the aforementioned drain region and source region forming step) are performed in this order after the channel-stopper region forming step. Thereby, a structure illustrated in FIG. 3C is obtained.

The gate insulation film forming step is defined to form the gate insulation film 45 made of a silicon dioxide film (thermally-oxidized film) on the surface of the silicon substrate 1 by means of the thermal oxidization.

The temperature detection element forming step is defined to form the temperature detection element 36 on the thermal insulation layer 33. The temperature detection element forming step includes a polysilicon layer forming step, a polysilicon layer patterning step, a p-type polysilicon layer forming step, and an n-type polysilicon layer forming step. The polysilicon layer patterning step is performed after the polysilicon layer forming step. The p-type polysilicon layer forming step is performed after the polysilicon layer patterning step. The n-type polysilicon layer forming step is performed after the p-type polysilicon layer forming step.

The polysilicon layer forming step is defined to form a non-doped polysilicon layer having a predetermined film thickness (e.g., 3000 A) on the whole of the surface of the silicon substrate 1 by use of LPCVD technique. The non-doped polysilicon layer is used as a base for forming the gate electrode 46, the polysilicon line 8b, the horizontal signal lines 6, the n-type polysilicon layer 34, and the p-type polysilicon layer 35.

In the polysilicon patterning step, by use of the photolithography technique and the etching technique, the non-doped polysilicon layer is patterned in order to leave portions thereof respectively corresponding to the gate electrode 46, the polysilicon line 8b, the horizontal signal lines 6, and the polysilicon layers 34 and 35.

The p-type polysilicon layer forming step is defined to perform the ion implantation of a p-type impurity (e.g., BF) to a portion of the non-doped polysilicon layer corresponding to the p-type polysilicon layer 35, followed by the drive diffusion, thereby forming the p-type polysilicon layer 35. The p-type polysilicon layer 35 has residual stress of −300 MPa.

The n-type polysilicon layer forming step is defined to perform the ion implantation of an n-type impurity (e.g., phosphors) to a portion of the non-doped polysilicon layer corresponding to the n-type polysilicon layer 34, followed by the drive diffusion, thereby forming the n-type polysilicon layer 34. The n-type polysilicon layer 34 has residual stress of −300 MPa.

The gate/source/drain forming step is defined to perform the ion implantation of an n-type impurity (e.g., phosphors) to portions of the non-doped polysilicon layer respectively corresponding to the gate electrode 46, the polysilicon line 8b, and the horizontal signal lines 6 together with regions of the well region 41 respectively reserved for forming the drain region 43 and the source region 44. After that, the drive diffusion is performed to form the gate electrode 46, the polysilicon line 8b, the horizontal signal lines 6, the drain region 43, and the source region 44. Besides, in the gate/source/drain forming step, a part of the non-doped polysilicon layer to be the gate electrode 46 acts as a mask which prevents the n-type impurity from being implanted to a region below the gate electrode 46 during the ion implantation. That is, in the gate/source/drain forming step, the drain region 43 and the source region 44 are formed by use of the known self alignment technique.

In the present embodiment, process temperatures of each of the steps (the gate insulation film forming step, the polysilicon layer forming step, the polysilicon layer patterning step, the p-type polysilicon layer forming step, the n-type polysilicon layer forming step, the gate/source/drain forming step) are selected not to exceed the temperature of formation of the thermal insulation layer 33 (1100 deg C., in the present embodiment). Consequently, the thermal insulation layer 33 sees no substantial change in its residual stress.

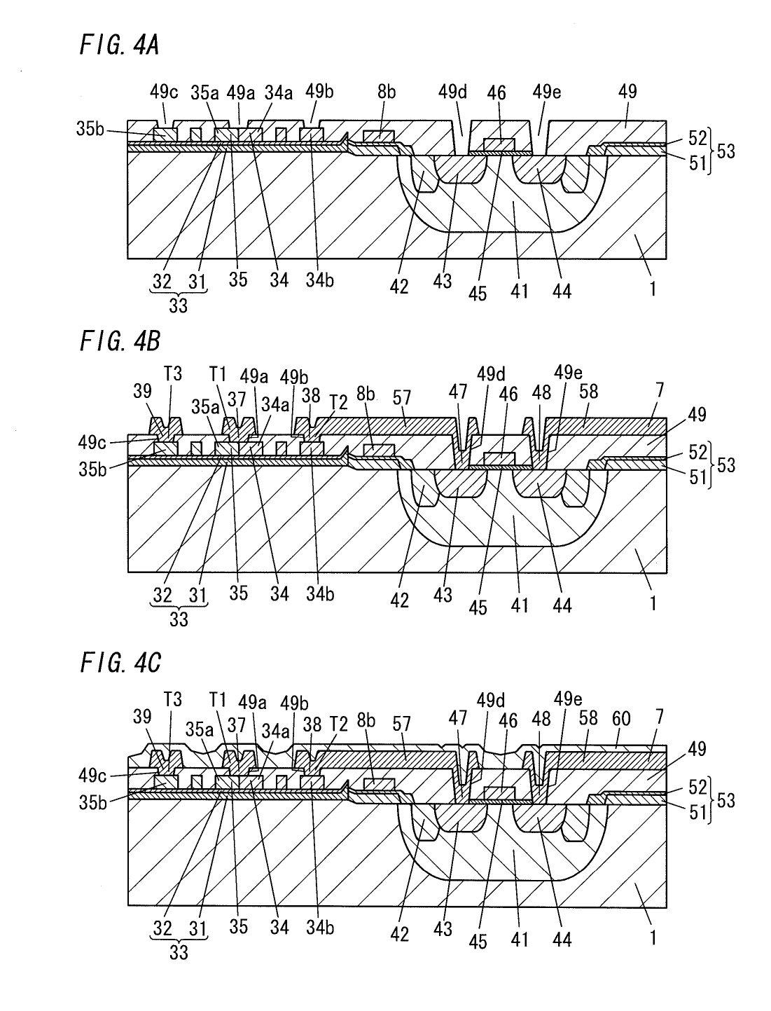

After the gate/source/drain forming step, with performing the interlayer dielectric film forming step followed by the contact hole forming step, a structure illustrated in FIG. 4A is obtained.

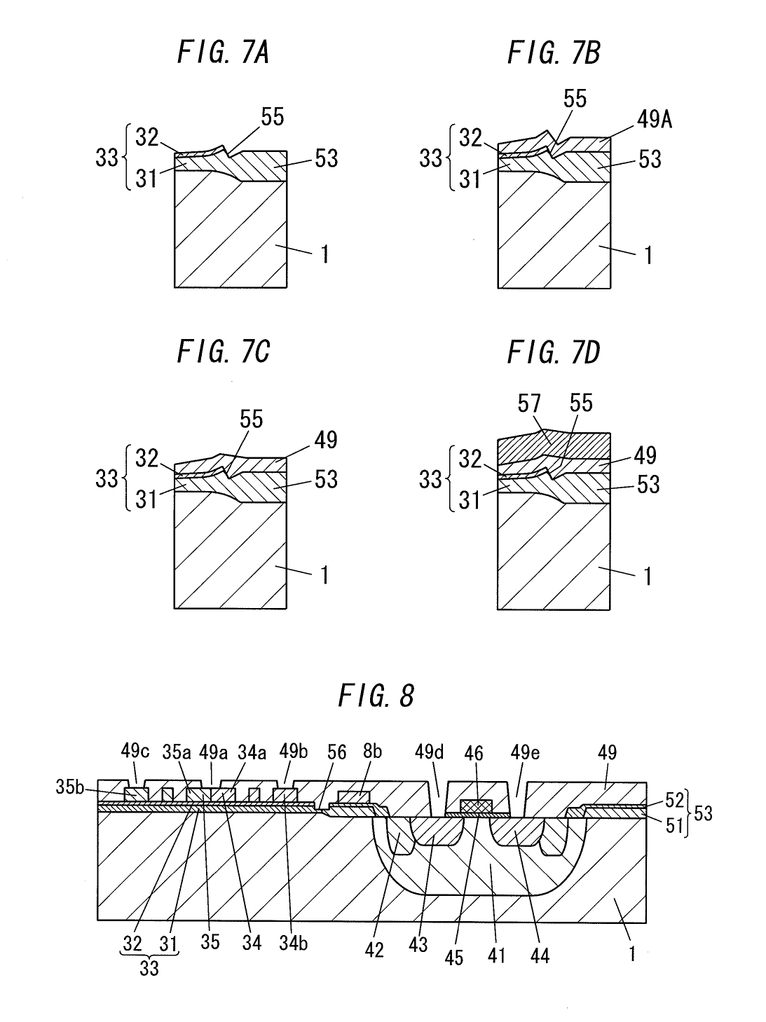

The interlayer dielectric film forming step is defined to form the interlayer dielectric film 49 over the surface of the silicon substrate 1. Especially, in the interlayer dielectric film forming step, the planarized interlayer dielectric film 49 (see FIG. 7C) is formed by depositing a BPSG film 49A (see FIG. 7B) having a predetermined film thickness (e.g., 6500 A) over the surface of the silicon substrate 1 by use of CVD technique followed by reflowing the deposited BPSG film 49A at a predetermined temperature (e.g. 800 deg C.).

The contact hole forming step is a step of forming the contact holes 49a to 49e in the interlayer dielectric film 49 by use of the photolithography technique and the etching technique.

By performing the metal line forming step of forming the metal line 57 designed to connect the temperature detection element 36 with the MOS transistor 4 after the contact hole forming step, a structure illustrated in FIG. 4B is obtained.

The metal line forming step includes a metal film forming step, and a metal film patterning step which is performed after the metal film forming step.

The metal film forming step is defined to form, over the whole of the surface of the silicon substrate 1, a metal film having a predetermined film thickness (e.g., 1 μm) by use of the sputtering. The above metal film is a base for forming each of the electrodes 37, 38, and 39, the drain electrode 47, the source electrode 48, each of the metal lines 8a, 57, 58, and 59, and the each pad 9.

The metal film patterning step is defined to pattern the metal film by use of the photolithography technique and the etching technique to form each of the electrodes 37, 38, and 39, the drain electrode 47, the source electrode 48, each of the metal lines 8a, 57, 58, and 59, and the each pad 9. In the metal film patterning step, the metal film is etched by use of RIE.

By performing the passivation film forming step after the metal film patterning step, a structure illustrated in FIG. 4C is obtained.

The passivation film forming step is defined to form the passivation film 60 over the whole of the surface of the silicon substrate 1 (in other words, on the interlayer dielectric film 49) by use of CVD technique. The passivation film 60 is a laminated film including a PSG film having a predetermined film thickness (e.g., 0.2 μm) and an NSG film having a predetermined film thickness (e.g., 0.2 μm).

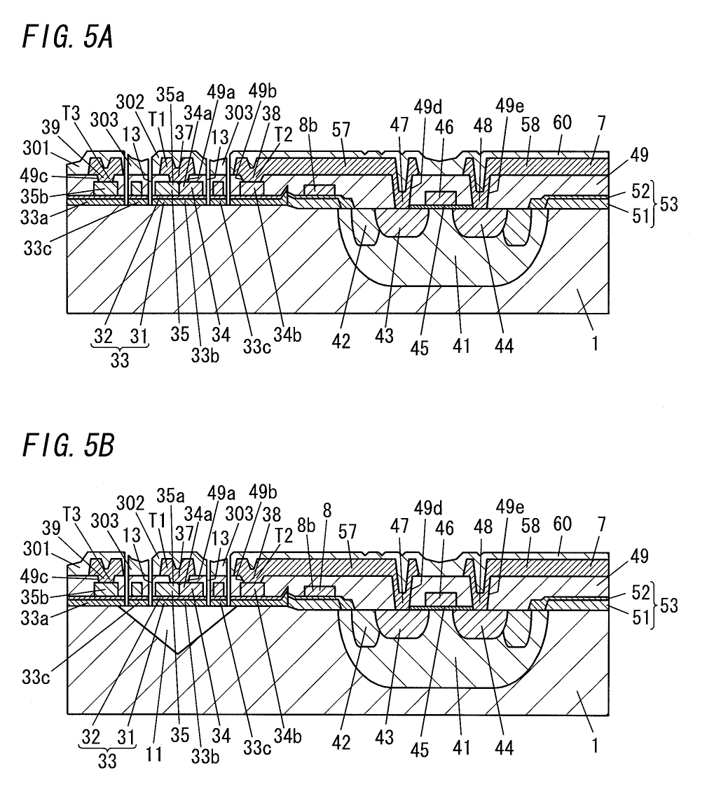

By performing a laminate structure patterning step after the passivation film forming step, a structure illustrated in FIG. 5A is obtained.

The laminate structure patterning step is defined to pattern a laminate (laminate structure) composed of the thermal insulation layer 33, the temperature detection element 36 formed on the thermal insulation layer 33, the interlayer dielectric film 49 formed over the thermal insulation layer 33 to cover the temperature detection element 36, and the passivation film 60 formed on the interlayer dielectric film 49, thereby forming the infrared detection element 3 (the structure composed of the infrared absorption member 302, each beam member 303, and the supporting member 301). Besides, the laminate structure patterning step includes a step of forming a plurality of slits 13 each of which penetrates the laminate structure along a thickness direction thereof and separates the infrared absorption member 302 from the supporting member 301. The above structure is completed by forming these slits 13.

By performing an opening forming step followed by the cavity forming step after the laminate structure patterning step, the infrared image sensor including pixels each having the structure which is illustrated in FIG. 5B is obtained.

The opening forming step is defined to form openings (not shown) by use of the photolithography technique and the etching technique. Each of the openings is designed to expose the corresponding pad 9. In the opening forming step, the openings are formed by use of RIE.

The cavity forming step is defined to make anisotropic etching of the silicon substrate 1 by pouring an etchant into the slits 13 and 13 to form the cavity 11 in the silicon substrate 1. In other words, in the cavity forming step, the slits 13 and 13 are used as an etchant conduit. In the cavity forming step, an alkaline solution (TMAH solution, in the present embodiment) is adopted as the etchant.

Besides, all the steps from the thermal insulation layer forming step to the cavity forming step are performed at wafer level. Therefore, after completion of the cavity forming step, a separation step is made to separate the infrared image sensors from each other.

In addition, as apparent from the above explanation, with regard to a method for forming the MOS transistor 4, a known and common manufacturing method of MOS transistors is adopted. In other words, with repeat of basic steps (e.g., a step of forming a thermally-oxidized film by use of thermal oxidization, a step of patterning the thermally-oxidized film by use of the photolithography technique and the etching technique, a step of implementing an impurity, and a step of performing drive-in diffusion), the well region 41, the channel-stopper region 42, the drain region 43, and the source region 44 are formed.

As explained in the above, the method for manufacturing the infrared image sensor of the present embodiment includes the thermal insulation layer forming step, the well region forming step, the gate insulation film forming step, the temperature detection element forming step, the drain region and source region forming step, the interlayer dielectric film forming step, the passivation film forming step, and the cavity forming step. The thermal insulation layer forming step is defined as a step of forming the thermal insulation layer 33 over the first area A1 of the surface of the silicon substrate 1. The thermal insulation layer 33 includes the silicon dioxide film 31 given compression stress, and the silicon nitride film 32 given tensile stress. The well region forming step after the thermal insulation layer forming step is defined as a step of forming the well region 41 having the first conductivity type (p⁺-type) formed in the second area A2 of the surface of the silicon substrate. The gate insulation film forming step after the well region forming step is defined as a step of thermally oxidizing the surface of the silicon substrate 1 to form the gate insulation film 45. The temperature detection element forming step after the gate insulation film forming step is defined as a step of forming, on the thermal insulation layer 33, the temperature detection element 36 configured to detect a temperature variation. The drain region and source region forming step after the temperature detection element forming step is defined as a step of forming the drain region 43 and the source region 44 within the well region 41. The interlayer dielectric film forming step after the drain region and source region forming step is defined as a step of forming the interlayer dielectric film 49 over the surface of the silicon substrate 1. The passivation film forming step after the interlayer dielectric film forming step is defined as a step of forming the passivation film 60 on the interlayer dielectric film 49. The cavity forming step after the passivation film forming step is defined as a step of forming the cavity 11 in the silicon substrate 1.

In the method for manufacturing the infrared image sensor of the present embodiment, the thermal insulation layer 33 is completed by forming the silicon nitride film 32 on the silicon dioxide film 31 prior to formation of the MOS transistor 4. In contrast to the silicon dioxide film 31, the silicon nitride film 32 is hard to be oxidized.

According to the method for manufacturing the infrared image sensor of the present embodiment, although the thermal oxidization is performed in the process of manufacturing the MOS transistor 4, it is possible to prevent the thermal insulation layer 33 from being thermally oxidized. As a result, the thermal insulation layer 33 can be free from change in at least one of the film thickness and the film configuration. Further, since the thermal insulation layer 33 is completed by forming the silicon nitride film 32 having tensile stress on the silicon dioxide film 31 having compression stress, it is possible to provide the infrared image sensor which is capable of making infrared detection elements thin, yet keeping the infrared absorption member 302 and the respective beam members 301 of the infrared detection element 3 free from warp. Further, in the present embodiment, since a thermoelectric material of the temperature detection element 36 is a polysilicon, the method of the present embodiment suits the method for manufacturing the MOS transistor 4. Therefore, it is possible to decrease the number of steps of the method for manufacturing the infrared image sensor.

Additionally, in the infrared image sensor of the present embodiment, the silicon nitride film 32 is formed on the surface of the silicon substrate 1 with the exception of the second area A2 which is used for forming the MOS transistor 4. Therefore, as described in the above, with adoption of the process of manufacturing the well region 41, the gate insulation film 45, the drain region 43, and the source region 44 of the MOS transistor 4 in subsequence to the formation of the thermal insulation layer 33, it is possible to prevent the oxidization of the thermal insulation layer 33 which would otherwise occur in the process of manufacturing the MOS transistor 4. Consequently the thermal insulation layer 33 can be free from change in at least one of the film thickness and the film configuration. Moreover, the thermal insulation layer 33 comprises the silicon dioxide film 31 having a compression stress, and the silicon nitride film 32 having a tensile stress and formed on the silicon dioxide film 31. Therefore, even if the MOS transistor 4 is formed by use of a common method, it is possible to make the infrared detection element 3 thin, yet keeping it free from warp. Besides, in the infrared image sensor of the present embodiment, the silicon nitride film 32 is not formed on the second area A2. However, the silicon nitride film 32 may be formed over the surface of the silicon substrate 1 at a portion at least except for a projected area of the well region 41 of the MOS transistor 4 projected in its thickness direction (i.e., the silicon nitride film may be formed not to be overlapped with the well region 41 in its thickness direction).

In addition, the infrared detection element 3 is formed to satisfy both the following formulae (1) and (2).

[Formula 3]

∫_{-t/2}^{t/2}σₘ(y)dy=0 (1)

[Formula 4]

∫_{-t/2}^{t/2}σₘ(y)·ydy=0 (2)

In the above formulae, y denotes a distance from a center of the infrared detection element 3 along a direction (vertical direction, in FIG. 1C) aligned with a thickness direction of the infrared detection element 3, and sₘ(y) denotes a stress of the infrared detection element 3, and t denotes a thickness of the infrared detection element 3.

In the present embodiment, a formation condition for the infrared detection element 3 is selected to satisfy the formulae (1) and (2). Notably, when the formula (1) is satisfied, it is possible to reduce residual stress of the infrared detection element 3 down to zero. In addition, when the formula (2) is satisfied, it is possible to reduce a bending moment of the infrared detection element 3 down to zero. Therefore, the infrared detection element 3 can be free from warp.

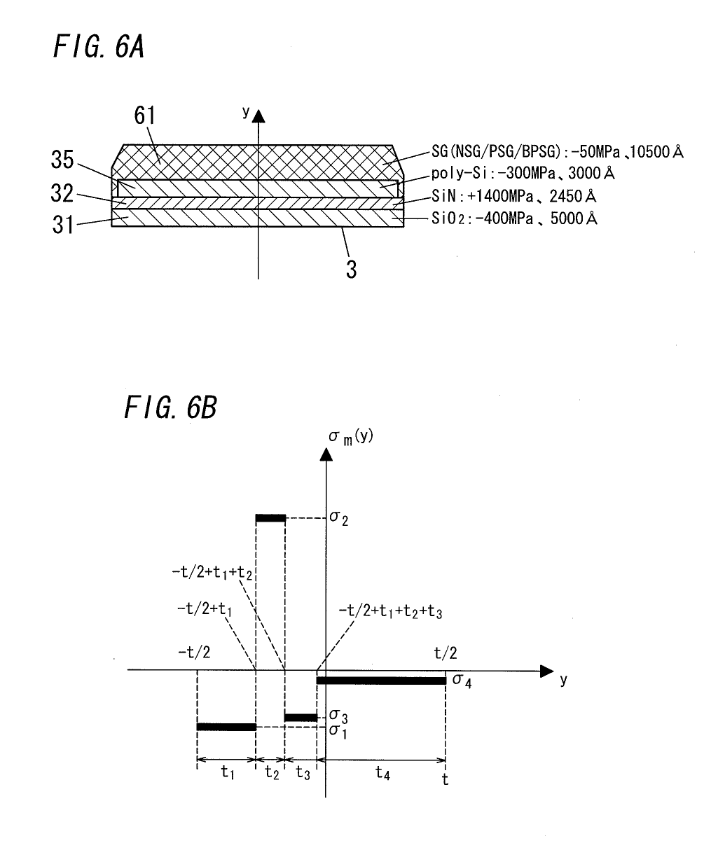

As shown in FIG. 6A, the infrared detection element 3 has a laminated structure in which the silicon dioxide film 31, the silicon nitride film 32, the polysilicon layer 35 (or polysilicon layer 34), and an SG film 61 are laminated in this order. The SG (Silicate Glass) film 61 is a laminated film which comprises the interlayer dielectric film 49 made of the BPSG film and the passivation film 60 made of the NSG film and the PSG film.

Therefore, the above formulae (1) and (2) can be rewritten as the following formulae (3) and (4), respectively. With regard to the following formulae (3) and (4), s₁(y) denotes a stress of the silicon dioxide film 31, and s₂(y) denotes a stress of the silicon nitride film 32, and s₃(y) denotes a stress of the polysilicon layer 35, and s₄(y) denotes a stress of the SG film 61. Further, t₁ denotes a thickness of the silicon dioxide film 31, and t₂ denotes a thickness of the silicon nitride film 32, and t₃ denotes a thickness of the polysilicon layer 35, and t₄ denotes a thickness of the SG film 61. Further, t satisfies a relation of t=t₁+t₂+t₃+t₄.

[Formula 5]

∫_{-t/2}^{-t/2+t}^{₁}σ₁(y)dy+∫_{-t/2+t}_{₁}^{-t/2+t}^{₁}^{+t}^{₂}σ₂(y)dy+∫_{-t/2+t}_{₁}₊ₜ_{₂}^{-t/2+t}^{₁}^{+t}^{₂}^{+t}^{₃}σ₃(y)dy+∫_{-t/2+t}_{₁}₊ₜ_{₂}₊ₜ_{₃}^{t/2}σ₄(y)dy=0 (3)

[Formula 6]

∫_{-t/2}^{-t/2+t}^{₁}σ₁(y)·ydy+∫_{-t/2+t}_{₁}^{-t/2+t}^{₁}^{+t}^{₂}σ₂(y)·ydy+∫_{-t/2+t}_{₁}₊ₜ_{₂}^{-t/2+t}^{₁}^{+t}^{₂}^{+t}^{₃}σ₃(y)·ydy+∫_{-t/2+t}_{₁}₊ₜ_{₂}₊ₜ_{₃}^{t/2}σ₄(y)·ydy=0 (4)

Further, the method of manufacturing the infrared image sensor according to the present embodiment has the thermal insulation layer forming step in which the formation temperature (that is, lower one of the formation temperature of the silicon dioxide film 31 and the formation temperature of the silicon nitride film 32) of the thermal insulation layer 33 is selected to be higher than any process temperature in all the steps performed after the thermal insulation layer forming step (in the present embodiment, the formation temperature of the thermal insulation layer 33 is 1100 deg C.). In brief, the method comprises a step of keeping a temperature of the silicon dioxide film 31 less than a temperature required for forming the silicon dioxide film 31 and of keeping a temperature of the silicon nitride film 32 less than a temperature required for forming the silicon nitride film 32, after the thermal insulation layer forming step. Therefore, each of the silicon dioxide film 31 and the silicon nitride film 32 can retain its thickness and stress free from undesired effect which would be otherwise caused by a process temperature in a subsequent step after the thermal insulation layer forming step. Consequently, the infrared detection element 3 can be successfully free from warp.

With regard to the method for manufacturing the infrared image sensor of the present embodiment, in the well region forming step, as shown in FIG. 7A, the thermally-oxidized film 53, which is adjacent to the second area A2, is formed on the surface of the silicon substrate 1. This thermally-oxidized film 53 comprises the aforementioned silicon dioxide films 51 and 52.

As shown in FIG. 7A, a height difference occurs at a border 55 between the thermally-oxidized film 53 and the thermal insulation layer 33. In other words, a step is developed between the thermally-oxidized film 53 and the thermal insulation layer 33.

As described in the above, in the interlayer dielectric forming step, as shown in FIG. 7B, the interlayer dielectric film 49 is formed by depositing the BPSG film 49A over the surface of the silicon substrate 1 followed by reflowing the same. With this manner, it is possible to form the planarized interlayer dielectric film 49 as shown in FIG. 7C. The metal line 57 is formed on the planarized interlayer dielectric film 49, as shown in FIG. 7D.

Therefore, according to the method of manufacturing the infrared image sensor of the present embodiment, the interlayer dielectric film 49 can have an improved flatness, thereby making the metal line 57 free from partial undue reduction in thickness and therefore avoiding breakage of the metal line, and also avoiding breakage due to an excess thermal stress.

### Second Embodiment

The infrared image sensor of the present embodiment is different from the infrared image sensor of the first embodiment in that the infrared image sensor of the present embodiment includes a recess 56. Besides, configurations to the infrared image sensor of the present embodiment and the infrared image sensor of the first embodiment are designated by the same reference numerals, and no explanations thereof are deemed necessary.

In the method for manufacturing the infrared image sensor of the present embodiment, by performing a recess forming step followed by the interlayer dielectric film forming step after the well region forming step, a structure illustrated in FIG. 8 is obtained.

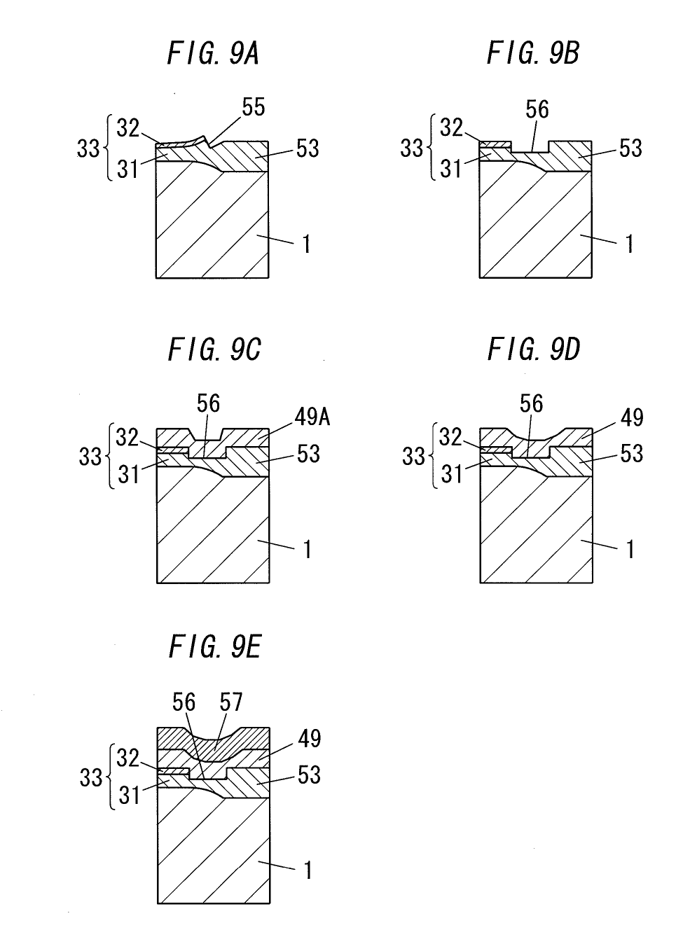

The recess forming step is defined as a step of forming a recess 56 for decreasing the height difference by use of the photolithography technique and the etching technique, as shown in FIG. 9B. The recess 56 is formed in the thermal insulation layer 33 and the thermally-oxidized film 53 along the border 55 (see FIG. 9A). Additionally, the recess 56 is formed to have a depth which is small relative to the height difference between the thermal insulation layer 33 and the thermally-oxidized film 53.

Like the first embodiment, the interlayer dielectric forming step after the recess forming step is defined as a step of depositing the BPSG film 49A over the surface of the silicon substrate 1 followed by reflowing of the same as shown in FIG. 9C to form the planarized interlayer dielectric film 49 as shown in FIG. 9D.

By performing the metal line forming step of forming the metal line 57 after the interlayer dielectric film forming step, a structure illustrated in FIG. 9E is obtained.

In the method for manufacturing the infrared image sensor as mentioned in the above, the recess 56 is formed at the border 55 between the thermal insulation layer 33 and the thermally-oxidized film 53 to have a depth which is small relative to the height difference between the thermal insulation layer 33 and the thermally-oxidized film 53 after the well region forming step and before the interlayer dielectric film forming step.

According to the method of manufacturing the infrared image sensor of the present embodiment, the interlayer dielectric film 49 can have a more improved flatness than that of the first embodiment, thereby making the metal line 57 free from partial undue reduction in thickness and therefore successfully avoiding breakage of the metal line, and also successfully avoiding breakage due to an excess thermal stress.

Further, the infrared image sensor of the present embodiment includes the recess 56 formed at the border 55 between the thermal insulation layer 33 and the thermally-oxidized film 53, the interlayer dielectric film 49 designed to cover the recess 56, and the metal line 57 formed on the interlayer dielectric film 49. The interlayer dielectric film 49 is formed by means of reflowing the BPSG film 49A deposited over the surface of the silicon substrate 1.

According to the infrared image sensor of the present embodiment, the interlayer dielectric film 49 can have a more improved flatness than that of the first embodiment, thereby making the metal line 57 free from partial undue reduction in thickness and therefore successfully avoiding breakage of the metal line, and also successfully avoiding breakage due to an excess thermal stress.

1. A method for manufacturing an infrared image sensor, said infrared image sensor comprising:
a silicon substrate; and
a plurality of cells formed over a surface of said silicon substrate,
wherein each of said cells includes an infrared detection element configured to detect an infrared, and a MOS transistor configured to read out an output of said infrared detection element, said MOS transistor being arranged adjacent to said infrared detection element,
said silicon substrate being provided with cavities for thermal insulation in its portions respectively corresponding to said infrared detection elements of said cells,
each of said infrared detection elements including a thermal insulation layer formed over said surface of said silicon substrate, and a temperature detection element formed on said thermal insulation layer,
said thermal insulation layer including a silicon dioxide film for thermal insulation formed on said surface of said silicon substrate, and a silicon nitride film for thermal insulation formed on said silicon dioxide film, said silicon dioxide film having compression stress, said silicon nitride film having tensile stress,
said temperature detection element being configured to absorb infrared and detect temperature change resulting form infrared absorption, and
said MOS transistor including a well region of a first conductivity type formed in said surface of said silicon substrate, a drain region of a second conductivity type formed in said well region, a source region of the second conductivity type formed in said well region so as to be away from said drain region, and a gate insulation film formed on a part of said well region formed between said drain region and said source region, and
said method comprising:
a thermal insulation layer forming step of forming said thermal insulation layer over a first area of said surface of said silicon substrate;
a well region forming step of forming said well region formed in a second area of said surface of said silicon substrate after said thermal insulation layer forming step;
a gate insulation film forming step of forming said gate insulation film by means of thermal oxidation of said surface of said silicon substrate after said well region forming step;
a temperature detection element forming step of forming said temperature detection element after said gate insulation film forming step;
a drain region and source region forming step of forming said drain region and said source region after said temperature detection element forming step; and
a cavity forming step of forming said cavity after said drain region and source region forming step.

2. A method for manufacturing the infrared image sensor as set forth in claim 1, wherein
said method further comprises:
an interlayer dielectric film forming step of forming an interlayer dielectric film over said surface of said silicon substrate by depositing a BPSG film over said surface of said silicon substrate followed by reflowing the deposited BPSG film, after said drain region and source region forming step and before said cavity forming layer;
a metal line forming step of forming a metal line electrically connecting said temperature detection element with said MOS transistor, after said interlayer dielectric film forming step and before cavity forming step; and
a passivation film forming step of forming a passivation film on said interlayer dielectric film, after said metal line forming step and before said cavity forming step.

3. A method for manufacturing the infrared image sensor as set forth in claim 2, wherein
said method further comprises a recess forming step of forming a recess, after said well region forming step and before said interlayer dielectric film forming step,
said well region forming step including a step of forming a thermally-oxidized film on said second area so as to be adjacent to said thermal insulation layer, and
said recess forming step including a step of forming, at a border between said thermal insulation layer and said thermally-oxidized film, said recess having a depth of said recess which is small relative to a height difference between said thermal insulation layer and said thermally-oxidized film.

4. A method for manufacturing the infrared image sensor as set forth in claim 1, wherein
said method further comprises a step of forming said infrared detection element to satisfy following two formulae:
∫_{-t/2}^{t/2}σₘ(y)dy=0
∫_{-t/2}^{t/2}σₘ(y)·ydy=0
wherein y denotes a distance from a center of said infrared detection element along a direction aligned with a thickness direction of said infrared detection element, and
sₘ(y) denotes a stress of said infrared detection element, and
t denotes a thickness of said infrared detection element.

5. A method for manufacturing the infrared image sensor as set forth in claim 1, further comprising a step of keeping a temperature of said silicon dioxide film less than a temperature required for forming said silicon dioxide film and of keeping a temperature of said silicon nitride film less than a temperature required for forming said silicon nitride film, after said thermal insulation layer forming step.

6. An infrared image sensor comprising:
a silicon substrate; and
a plurality of cells formed over a surface of said silicon substrate,
wherein each of said cells includes an infrared detection element configured to detect an infrared, and a MOS transistor configured to read out an output of said infrared detection element, said MOS transistor being arranged adjacent to said infrared detection element,
said silicon substrate being provided with cavities for thermal insulation in its portions respectively corresponding to said infrared detection elements of said cells,
each of said infrared detection elements including a thermal insulation layer formed over said surface of said silicon substrate, and a temperature detection element formed on said thermal insulation layer,
said thermal insulation layer including a silicon dioxide film for thermal insulation formed on said surface of said silicon substrate, and a silicon nitride film for thermal insulation formed on said silicon dioxide film, said silicon dioxide film having compression stress, said silicon nitride film having tensile stress,
said temperature detection element being configured to absorb infrared and detect temperature change resulting form infrared absorption, and
said MOS transistor including a well region of a first conductivity type formed in said surface of said silicon substrate, a drain region of a second conductivity type formed in said well region, a source region of the second conductivity type formed in said well region so as to be away from said drain region, and a gate insulation film formed on a part of said well region formed between said drain region and said source region, and wherein
said silicon nitride film is formed not to be overlapped with said well region in its thickness direction.

7. An infrared image sensor as set forth in claim 6, wherein
said infrared image sensor comprises:
a thermally-oxidized film formed over said surface of said silicon substrate so as to be adjacent to said thermal insulation layer;
an interlayer dielectric film formed over said surface of said silicon substrate so as to cover a border between said thermal insulation layer and said thermally-oxidized film; and
a metal line formed on said interlayer dielectric film so as to connect said temperature detection element with said MOS transistor,
said interlayer dielectric film being formed by means of reflowing a BPSG film deposited over said surface of said silicon substrate.

8. An infrared image sensor as set forth in claim 6, wherein
said infrared image sensor comprises:
a thermally-oxidized film formed over said surface of said silicon substrate so as to be adjacent to said thermal insulation layer;
a recess formed at a border between said thermal insulation layer and said thermally-oxidized film;
an interlayer dielectric film formed over said surface of said silicon substrate so as to cover said recess; and
a metal line formed on said interlayer dielectric film so as to connect said temperature detection element with said MOS transistor,
said interlayer dielectric film being formed by means of reflowing a BPSG film deposited over said surface of said silicon substrate.
